(19) United States
(12) Patent Application Publication
(10) Pub. No.: US 2012/0307552 A1
(43) Pub. Date: Dec. 6, 2012

(54) Process of producing a resistivity-change memory cell intended to function in a high-temperature environment

(75) Inventors: Luca PERNIOLA, Noyarey (FR); Veronique SOUSA, Grenoble (FR)

(73) Assignee: COMMISSARIAT A L'ENERGIE ATOMIQUE ET AUX ENE. ALT., Paris (FR)

(21) Appl. No.: 13/152,917

(22) Filed: Jun. 3, 2011

(51) Int. Cl. G11C 11/00; H01L 45/00; H01L 21/06

(52) U.S. Cl. 365/163; 438/102; 257/2; 257/E21.068; 257/E21.004; 257/E45.001; 365/148

(57) ABSTRACT

A process of producing a resistivity-change memory cell is described. The process includes a deposition at room temperature, in amorphous state, of a layer of a nitrogen (N)-doped alloy of germanium (Ge) and tellurium (Te) to constitute the resistivity-change material of the memory cell. An annealing is then performed such as to limit the type of re-crystallisation by nucleation starting from the amorphous state of the phase-change material. The material used and the process permit the data retention at high temperature to be significantly improved.

### TECHNICAL FIELD OF THE INVENTION

This invention concerns resistive non-volatile memories, more particularly those using a phase change material, that are intended to function in an environment where high temperatures have to be withstood without that affecting either the retention time of the stored data or the life duration of these memories.

### STATE OF THE ART

PCM memories, an acronym for “phase-change memory”, use a material with an atomic structure that can be made to vary reversibly with the application of heat. The material constituting the memory element can change between two principal solid phases: one where the material adopts an orderly crystalline structure characterised by a weak electrical resistance, and the other where the atomic structure is not orderly or amorphous and shows a strong electrical resistance. Some intermediate states exist that can be exploited to obtain multi-level memory elements.

In PCM type electronic memories, the passage of a programming current causes the phase-change material to heat up and switch between its different phases. By controlling the durations and waveforms of the programming pulses, a stable resistant state that can be read using suitable peripheral circuits is obtained after cooling. Traditionally, the programming current and operation permitting a re-crystallisation of the phase-change material and, hence, the recording of a weak resistance value have been designated as “SET”. The programming current and operation known as “RESET” then cause the phase-change material to become amorphous, generally partially so, until it reaches a higher predetermined resistive state that, in combination with the weak resistance of the crystalline state, will be characteristic of the data stored by the memory element. Possibly more than two resistant states are programmable, allowing the memory capacity of each element to be increased.

For that matter, in this type of memory, a phase-change material is positioned between a heating means and an electric contact. The application of an electrical write pulse between the means of heating and the electric contact causes, by means of the Joule effect, the initially crystalline phase-change material to melt. The cessation of the pulse provokes a rapid hardening, leading to the amorphous phase of the phase-change material (a strongly resistant or non-conducting state, which can be coded with the information “0” or “1”). The return to the initial state is achieved by applying a pulse of weaker intensity.

This pulse provokes the crystallisation of the phase-change material (a weakly resistant or conducting state, which can be coded with the information “0” or “1”).

The sense signal results from the difference in electrical resistance between the two phases, namely, between the amorphous phase and the crystalline phase.

Thus, electronic PCM memories are directly sensitive to the temperature of the environment in which they have to function. Traditionally designed to operate at temperatures of up to 85° C. over 10 years, current devices typically use a chalcogenide as phase-change material, notably an alloy of germanium (Ge) and tellurium (Te), known by the acronym GeTe, or an alloy of germanium (Ge), antimony (Sb) and tellurium (Te), known by the acronym GST. Memory cells integrating this type of alloy have been described in Fantini et al. (“Comparative assessment of GST and GeTe materials for application to Embedded Phase-Change Memory Devices”, First IEEE International Memory Workshop 2009, Monterey, Calif., May 10th-14th 2009). However, as mentioned in this document, these materials present a very low information retention time at high temperatures. In fact, at 175° C., the alloy of germanium, antimony and tellurium loses its data almost instantly, while the retention time for the alloy of tellurium and germanium at this same temperature is only in the order of some hundreds of seconds.

These devices are therefore not capable of operating reliably at higher temperatures. However, many industrial applications, the automobile industry for example, need to have circuits that can operate reliably at higher temperatures, typically of up to 150° C. In these conditions, the retention of data stored over a long period of time cannot be guaranteed as the temperature of the environment is itself likely to cause a re-crystallisation or an appreciable change in the amorphous states. It thus rapidly becomes impossible to recover the levels of resistance that have been programmed. The data stored on the memory cell is, therefore, lost.

Other proposals have been made involving the use of the element carbon in an alloy containing germanium (Ge) and tellurium (Te). However, known techniques for obtaining memory cells containing this alloy require complex and costly equipment and material. In particular, to obtain this alloy, a co-sputtering active chamber with three targets, one for each material Ge, Te and C is required.

Given the problems that the known memory cells present, one object of this invention is to offer a method for providing a memory cell with an improved retention duration at high temperatures and at an acceptable cost.

Other purposes, characteristics and advantages of this invention will become apparent upon examination of the following description and accompanying drawings. It is understood that other advantages can be included.

### SUMMARY OF THE INVENTION

An aspect of the invention relates to a method of producing a phase-change memory cell comprising the following steps:
a step of formation of a layer, in amorphous state, of a resistivity-change material formed from a nitrogen (N)-doped alloy of germanium (Ge) and tellurium (Te), the nitrogen (N) doping of the alloy being between 1.5% and 5%,
an annealing carried out so as to encourage a type of re-crystallisation by growth from the amorphous state of the said resistivity-change material.

It has turned out that this composition of the resistivity-change material allows data retention to be significantly improved. As will be shown below, nitrogen doping at between 1.5% and 5% encourages crystallisation by growth rather than by nucleation, and this leads to better data retention at high temperature. Moreover, the annealing step, prior to any use of the memory cell, also considerably encourages crystallisation by growth, and this permits the retention capacity to be improved even more, notably at high temperature.

Advantageously, such resistivity change material according to the invention can possibly be obtained through providing a flux of nitrogen into a chamber, which is much simpler and less expensive than having a target for each material of the alloy.

Following a preferred form of embodiment, the resistivity-change material is a phase-change material. It is formed to present an amorphous phase in one first state and to present a crystalline phase in at least one second state.

Another aspect of the invention relates to a non-volatile memory cell comprising a resistivity-change material configured to change state reversibly between at least two stable states that present different electrical resistances and in which if the resistivity-change material is a nitrogen (N)-doped alloy of germanium (Ge) and tellurium (Te), the nitrogen (N)-doping of the alloy is between 1.5% and 5%

According to another aspect, the invention relates to a non-volatile memory cell comprising a phase-change material configured to change phase reversibly between at least two stable phases that present different electrical resistances and formed in such a way that the passage from one phase to another is achieved by controlling the rise or fall in temperature of the phase-change material, characterised by the fact that the phase-change material is a nitrogen (N)-doped alloy of germanium (Ge) and of tellurium (Te), the nitrogen (N)-doping of the alloy being between 1.5% and 5%.

Another aspect of the invention relates to a device that integrates a memory cell in accordance with the invention and intended to be taken, at least partially, to a temperature equal to at least 100° C. This temperature is preferably more than 120° C. Typically, the device can be an automotive component or part.

Another aspect of this invention relates to a use of a memory cell in accordance with the invention; in the course of this use, the memory cell is subjected to a temperature equal to at least 100° C. The memory cell is preferably subjected to such a temperature for at least half of its normal time of use. Typically, the normal time of use of a memory cell incorporated into an automotive corresponds to the time that the vehicle is in use.

### BRIEF DESCRIPTION OF THE FIGURES

The goals and objectives as well as the characteristics and advantages of the invention will emerge better from the detailed description of an embodiment of this latter, illustrated by the following accompanying drawings in which:

FIG. 1 is a sectional view of an example of a common structure of phase-change resistant memory cell.

FIG. 2 compares two types of re-crystallisation of an amorphous zone in a phase-change memory cell.

FIG. 3 illustrates the behaviour of the types of re-crystallisation by nucleation and by growth in phase-change materials with respect to temperature.

FIGS. 4a and 4b illustrate the behaviour in time of the phase-change material in the invention, GeTe, at different levels of nitrogen-doping, and compare it with a traditional material, GST.

FIG. 5 describes the specific steps of an example manufacturing process according to the invention, in order to obtain a phase-change memory cell using the material of the invention.

FIG. 6 compares the types of GeTe re-crystallisation at two different levels of doping and shows that the re-crystallisation of GeTeN2% occurs mainly through growth.

The drawings attached are given as examples and are not limiting to the invention.

### DETAILED DESCRIPTION OF THE INVENTION

The main aspects of the invention, as well as of its non-limiting but nevertheless advantageous characteristics, shall now be mentioned, and then the invention will be described in detail.

A first aspect of the invention relates to a process of producing a phase-change memory cell comprising the following steps:
a step of formation of a layer, in amorphous form, of a resistivity-change material formed from a nitrogen (N)-doped alloy of germanium (Ge) and tellurium (Te), the nitrogen (N) doping of the alloy being between 1.5% and 5%,
an annealing carried out so as to encourage a type of re-crystallisation by growth from the amorphous form of the said resistivity-change material.

Optionally, the process according to the invention can also present at least one of any of the following characteristics and steps:
the step of formation comprises a deposition step of the layer of resistivity-change material at a temperature lower than 260° C. and preferably at room temperature, in amorphous form.
the annealing of the resistivity-change material is performed at a temperature ranging between 240° C. and 260° C. for a duration of between twenty and forty minutes. The duration is preferably between twenty-five and thirty-five minutes. The duration is even more preferably approximately thirty minutes.
the step of formation of the layer of the resistivity-change material produces a nitrogen (N)-doped alloy of germanium (Ge) and of tellurium (Te) in which the nitrogen-doping rate of the alloy is between 1.5% and 4% and more advantageously between 1.5% and 2.5%.
the step of formation of the layer of the resistivity-change material produces a nitrogen (N)-doped alloy of germanium (Ge) and tellurium (Te), the germanium (Ge) and the tellurium (Te) having a stoichiometric ratio close to one. For instance, with a doping of 2% of nitrogen, the alloy Ge52Te48 or the alloy Ge48Te52 may be used. A nitrogen doping may also be used with the alloy Ge53Te47 or the alloy Ge47Te53 or GeTe alloys having a stoichiometric ratio closer to 1.

the step of formation of the layer of a resistivity-change material comprises a deposition step of the said layer; this is achieved by sputtering germanium and tellurium in a sealed chamber where nitrogen is introduced. The nitrogen is preferentially introduced into the chamber in a proportion suitable to obtain a GeTeN alloy deposit doped to approximately 2%. Advantageously, obtaining nitrogen in a gaseous form and supplying it into a chamber is easy and not expensive.

As indicated above, the invention also has as objective a non-volatile memory cell comprising a resistivity-change material configured in order to change state reversibly between at least two stable states that present different electrical resistances and formed in such a way that the passage from one state to another is achieved by controlling the rise or fall in temperature of the resistivity-change material, the resistivity-change material being a nitrogen (N)-doped alloy of germanium (Ge) and tellurium (Te), the nitrogen (N)-doping of the alloy being between 1.5% and 5%.

Optionally, the memory cell according to the invention can also present at least one of any of the following characteristics:
the nitrogen-doping rate of the alloy is between 1.5% and 5%. The nitrogen-doping rate of the alloy is preferentially between 1.5% and 4% and more advantageously between 1.5% and 2.5%. The nitrogen-doping rate of the alloy is even more preferentially approximately 2%.
the alloy of germanium (Ge) and tellurium (Te) at a stoichiometric ratio close to one.

FIG. 1 illustrates, using a sectional view, an example of a common structure of phase-change resistant memory cell likely to benefit from the invention. Whatever its specific structure and dimensions, such a cell is characterised by the presence of a heater 10 with one of its ends directly in contact with a layer 20 constituted of a phase-change material 22. The heater 10 is generally embedded in a layer 50 of insulant, typically silicon oxide (SiO₂). As mentioned in the chapter on the prior art, the phase-change material is typically, for standard applications in an environment where the temperature does not exceed 85° C., made of GST, i.e. an alloy of germanium (Ge), antimony (Sb) and tellurium (Te).

As a replacement for the heater, a simple electrode can also be envisaged that would allow a current to pass through the phase-change material.

During a programming phase of the memory cell, using means not represented and which are not necessary to understanding the invention, a current is made to pass between the cell's lower 30 and upper 40 conducting electrodes through the heater 10 and the layer 20 of the phase-change material. It is the passage of current that brings about the heating that causes a change in the atomic structure of the phase-change material 22 in a zone 24 that develops from the side in contact with the heater 10. Depending on the embodiment, the heater is made of a material 12 that can be more or less electro-resistant. In a preferred way of implementing the invention, so that the heat supplied by the passage of the current develops principally in the phase-change material, the heater itself has a very low resistance. It is, for example, made of a metal such as tungsten (W), which can tolerate high temperatures without adverse effects.

Typically, the whole of the phase-change material layer 20 is initially in a low resistant crystalline phase or has been returned this state before programming the memory point. The current passing through the heater in preparation for programming the memory cell causes then, as shown in FIG. 1, a more or less extended zone 24 of the layer 20 to switch to an amorphous phase. This amorphous zone exhibits a resistance higher than that of the zone that has remained crystalline.

Putting the layer of the phase-change material back to the crystalline phase (SET) and switching the zone in contact with the heater into an amorphous phase (RESET) call for known techniques and procedures. Typically, as already mentioned above, pulses of current of controlled amplitude, duration and form are generated and enable the phase-change material to switch between its different states by controlling its heating and its cooling.

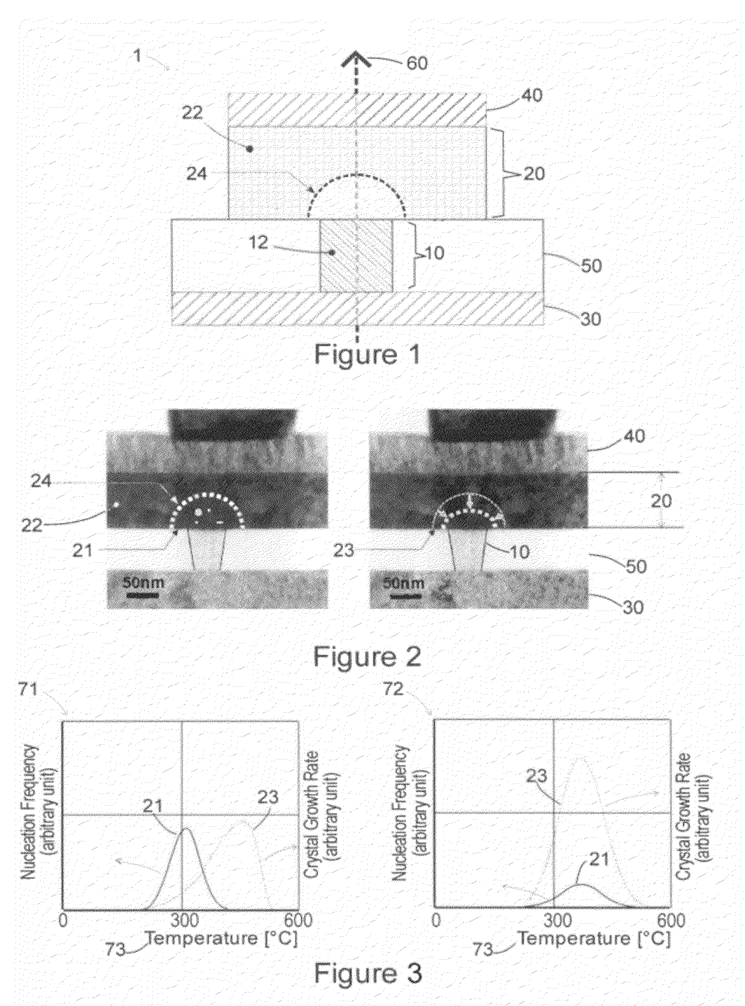

FIG. 2 compares two types of re-crystallisation that, after an amorphous zone 24 has been programmed, tend to lose the information stored by the memory cell, for example, under the effect of a high room temperature.

As illustrated on the left-hand side of FIG. 2, the amorphous zone 24 can re-crystallise through nucleation 21. Nuclei or seeds of crystallisation can then be observed forming spontaneously over the whole of the amorphous zone.

The re-crystallisation of the amorphous zone can also occur, as illustrated on the right-hand side of FIG. 2, by growth 23, starting from the crystalline zone of the layer 20 of resistivity-change material, towards the interior of the amorphous zone 24.

Nucleation and growth depend on the material under consideration and on the conditions of formation, notably temperature. Two representative examples, 71 and 72, of the behaviour of different materials are shown in FIG. 3. Examples 71 and 72 each illustrate the behaviour of a material. As can be observed, nucleation 21 and growth 23 can co-exist at different levels with respect to temperature 73. For a given material at a given temperature, one or the other of these types can be predominant compared to the other or, on the contrary, be non-existent.

As shall be seen below, one aspect of this invention rests on the observation that the type of re-crystallisation of the amorphous zone 24 by nucleation should preferentially be negligible in order to improve data retention, the lifespan of the memory cells. Thus, re-crystallisation of the amorphous zone 24 should preferentially occur through growth 23. This re-crystallisation occurring preferentially through growth has been observed in particular with a weakly nitrogen (N)-doped alloy of germanium (Ge) and tellurium (Te). Typically, the doping level recommended by the invention is in the region of 2%. This material shall henceforth be designated as GeTeN 2%. The results obtained with this material enable the invention objectives to be reached, i.e. a ten-year lifespan in an environment up to a temperature of 150° C.

In the context of the present invention, an x % doping of the GeTe alloy with a doping agent implies that the quantity of doping agent in this material is x %. The measurement may be obtained through a RBS-NRA which stands for Rutherford backscattering spectrometry-nuclear reaction analysis.

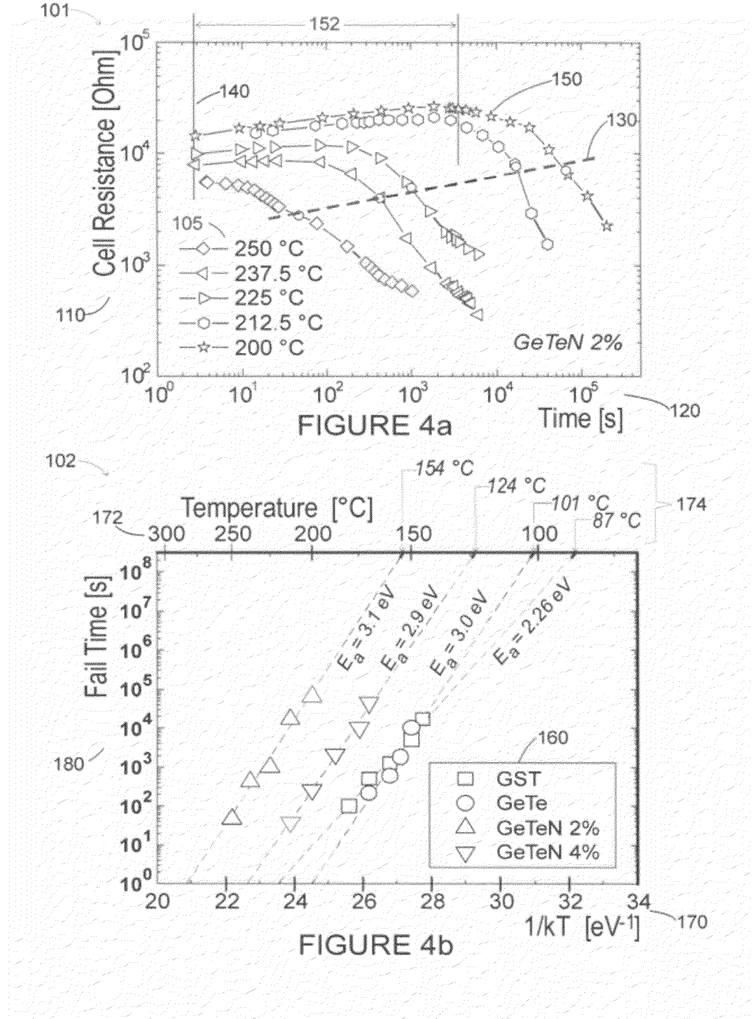

FIG. 4, composed of FIGS. 4a and 4b, shows the results obtained on samples of memory cells, as described in FIG. 1, whose layer 20 of resistivity-change material 22, traditionally GST, has been replaced by the material above, i.e. GeTeN 2%.

FIG. 4a shows the change in resistance of such a memory cell when subjected to very high temperatures, between 200° C. and 250° C.; these constitute stress conditions that will allow the lifespan of these devices to be assessed, as shall be seen in FIG. 4b. In diagram 101 of FIG. 4a, which shows the average change in resistance 110 of a large number of samples of memory cells over time 120, it is observed that the half value 130 of the initial resistance 140 at each of the stress temperatures 105 is, of course, reached more quickly the higher the temperature by reason of the amorphous zone re-crystallising more rapidly. However, it is also noticeable that for the least high temperatures, for example for the 200° C. curve, the resistance value continues to rise slowly for approximately one hour 152 before falling off rapidly. This shows that the size of the amorphous zone 24 remains practically unchanged during this period and that the nucleation process does not actually appear with the chosen material, i.e. GeTeN 2%. This aspect is discussed below, notably in FIG. 6.

The curves of diagram 101 in FIG. 4a are average geometric values measured for all of the samples. The recording and measurement of the change in resistance values over time for the memory cells occurs at the temperature in question, between 200° C. and 250° C., after the memory cell has been programmed initially, identically regardless of temperature, using a RESET pulse whereby a current is applied for a duration of 100 nanoseconds. The failure criterion, a harsh one, used to extrapolate the lifespan of the devices is when the initially programmed resistance has fallen by half; this corresponds to the straight line 130. It is a value that is taken to show that a significant re-crystallisation of the amorphous zone has taken place by then.

For comparison purposes, tests with other alloys were performed under identical conditions. They allow the activation energy (Eₐ) of the material under consideration to be determined, i.e. the energy that sets the chemical process of ageing in motion, and thus permit the lifespan of each of the materials to be extrapolated as shown in FIG. 4b.

In diagram 102, Arrhenius' law is used in the conventional way to account for the effect of temperature on the kinetics of ageing in the materials under consideration. The materials compared with the material recommended by the invention, GeTeN 2%, appear in the box 160. On the one hand, there is the traditional material, GST, and on the other, undoped GeTe and GeTe with a doubled nitrogen doping level (4%). As is conventional, the curves in the diagram are drawn against the inverse of the temperature 170. The temperature equivalent in degrees Celsius (° C.) is given in the top scale 172. The lifespan 180, measured at stress temperatures 105, is given on the y-axis for each of the materials under consideration. This lifespan is based, as seen above, on the reduction of the initial resistance value of the memory cells by half, corresponding to the straight line 130 in diagram 101. This allows the maximum operating temperatures assuring a lifespan of up to ten years, i.e. approximately 3×10⁸ seconds, to be extrapolated. These temperatures 174 appear above the diagram 102 and correspond to the intersection of the curves with the y-coordinate above 3×10⁸ seconds.

It is noticeable that the material recommended by the invention, GeTeN 2%, is significantly better than the other materials to which it is compared, in particular the traditional material, GST, for which the maximum operating temperature for a lifespan of ten years is just a little above the expected figure of 85° C. GeTeN 2% allows a operating temperature estimated at 154° C. and GeTeN 4% allows a temperature of 124° C. for a ten-year lifespan.

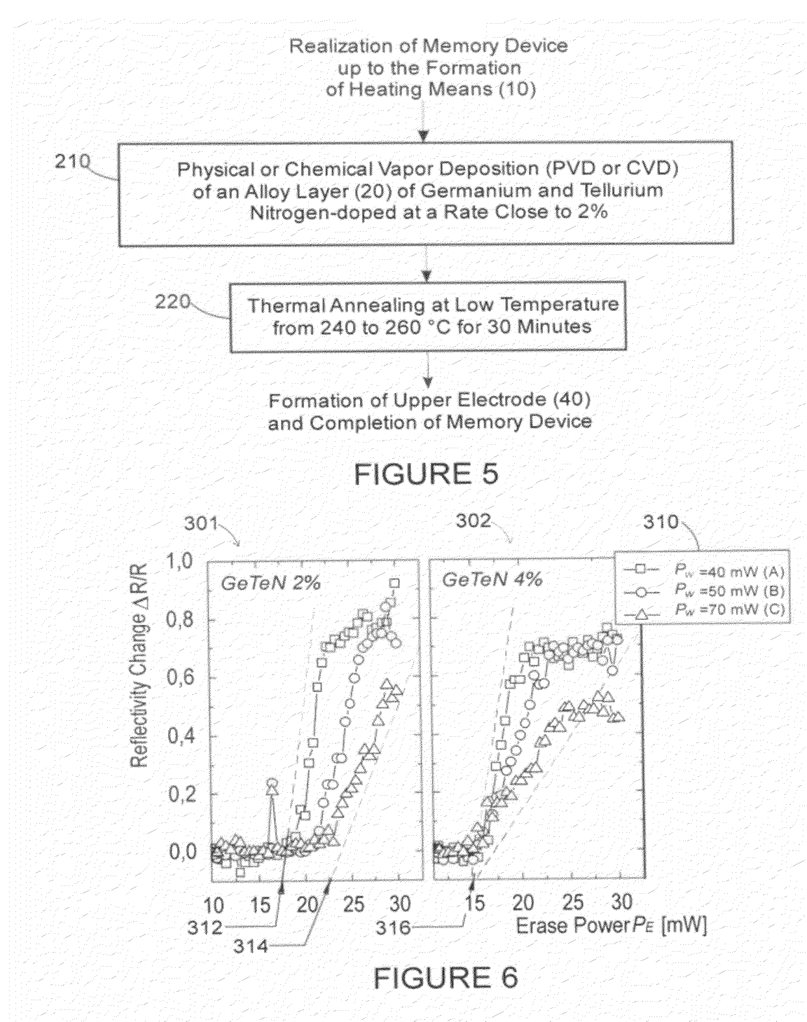

FIG. 5 shows the specific steps of a process wherein such results are possible.

After the formation of the heating means (heater) 10 in an insulating layer 50, as shown on FIG. 1, there follows the step of depositing 210 the layer of GeTeN x %, with x between 1.5 and 4, which constitutes the resistivity-change material of the invention. The deposition can be done by various means currently used in the microelectronic industry. This could namely be through “physical vapour deposition”, which includes a range of methods known by the acronym PVD, in particular a technique called “sputtering”. Sputtering is carried out in a sealed chamber, a deposition chamber, where a rarefied atmosphere containing the material to be deposited and permitting a cold plasma to be created is maintained. The source is often a magnetron. In the case where a layer of a GeTe alloy is deposited, a stoichiometric coefficient close to one is obtained by this method, i.e. germanium and tellurium appear in almost identical proportions in the alloy deposited. In the case of a uniform layer deposited on the totality of the surface of a substrate, the Ge/Te ratio has been measured at 53/47 using a technique called RBS, “Rutherford Backscattering Spectroscopy”. To dope the GeTe, nitrogen (N) is also introduced into the deposition chamber in a suitable proportion. The deposition is carried out in the presence of argon at a pressure of 0.005 millibars and at a cathode power of 100 watts at room temperature.

The deposition 210 can also be performed by “chemical vapour deposition” or CVD.

Since the GeTeN 2% layer is deposited at room temperature as described above, the layer deposited is entirely amorphous. Then in the next step 220, one proceeds to re-crystallise it by means of thermal annealing. The results described in FIG. 4b, which allow the objectives of the invention to be fulfilled with GeTeN 2%, are actually obtained with an optimal annealing performed at a relatively low temperature. In the framework of the development of this invention, it became apparent that the annealing should preferably be carried out at a temperature ranging from 240° C. to 260° C. for 30 minutes so that the stability of the amorphous phase of the GeTeN 2% would be the best possible by preventing or minimising re-crystallisation by nucleation and hence, by favouring re-crystallisation by growth, which guarantees a longer retention of stored data. According to an alternative embodiment, the thermal annealing is performed at the end of the process for obtaining the memory cell.

FIG. 6 compares how GeTe re-crystallises at the two doping levels shown in FIG. 4b (2% and 4%). They are compared in this case on the basis of optical measurements carried out on a substrate on which the material to be analysed has been deposited over its entire surface. The deposition is performed using the techniques mentioned above. So that the GeTe layer to be analysed optically does not oxidise on contact with the air, a protective layer that does not interfere with the optical measurements described below is also deposited.

FIG. 6 compares, with the help of the two diagrams 301 and 302, the results obtained with GeTeN 2% and GeTeN 4% respectively. The design concept of the optical measurements consists initially of using a laser to make the points of impact of the laser beam in a previously completely crystallised layer amorphous, thermally for example. As shown in the inset 310, three different driving forces P_{W}, associated with suitable durations t_{A}, t_{B} and t_{C}, are defined so as to be sufficient to cause amorphisation at the point of impact of the laser beam. The actual amorphisation of the material at the point of impact is verified afterwards through measuring the reflection coefficient observed at that place.

The diagrams in FIG. 6 show, on the y-axis, the variations in the reflection coefficient (ΔR/R) measured at each of the points of impact of the laser beam against the erase power P_{E} necessary to cause re-crystallisation with the laser, i.e. the erasure of the point of impact under consideration. In the curves in FIG. 6, the erase power P_{E}, which appears on the x-axis, is obtained with laser pulses of the same duration t_{E}.

With these curves it is possible to determine whether the material under consideration re-crystallises by nucleation or by growth on the basis of the following observation: if the power P_{E} necessary to cause re-crystallisation of the point of impact is the same, independent of the power P_{W} that was necessary to render it amorphous, then the re-crystallisation is principally occurring by nucleation, starting from seeds at the interior of the amorphous zone. On the contrary, if the power P_{E} necessary to cause re-crystallisation depends on the power P_{W}, the re-crystallisation is principally occurring by growth.

So it appears clearly on diagram 301, corresponding to the case of GeTeN 2%, that it really is mainly the latter which is observed using this material since the erase powers P_{E} 312 and 314 are indeed significantly dependent on the amorphisation powers P_{W}. On the contrary, with GeTeN 4%, as can be seen on the diagram 302, this dependence 316 does not exist.

This allows us to explain the much better behaviour of the material recommended by the invention, GeTeN 2%, whose amorphous zones are observed mainly to re-crystallise by growth after annealing under the conditions defined in FIG. 5, and with which much higher retention times at temperatures up to 150° C. are obtained, thus meeting the objectives of the invention.

Thus, by proposing a resistivity-change material with a very specific doping, and then by proposing preferentially an equally specific annealing step, this invention enables the retention capacity of memory cells to be very significantly improved.

The invention is not limited to the examples described and applies to any embodiment in keeping with its spirit.

Furthermore, some of the features of the exemplary embodiments of this invention may be used to advantage without the corresponding use of other features. As such, the foregoing description should be considered as merely illustrative of the principles, teachings and embodiments of this invention, and not in limitation thereof.

1. A method of producing a resistivity-change memory cell, said method comprising:
forming a layer, in an amorphous state, of a resistivity-change material formed of a nitrogen (N)-doped alloy of germanium (Ge) and tellurium (Te), the nitrogen (N)-doping of the alloy being between 1.5% and 5%, and
annealing performed in such a way as to limit a type of re-crystallisation by nucleation from the amorphous state of the resistivity-change material.

2. A method in accordance with claim 1 in which the step of forming comprises a deposition step of the layer of resistivity-change material, in an amorphous state, at temperature lower than 260° C.

3. A method in accordance with claim 1, wherein the annealing of the resistivity-change material is carried out at a temperature ranging between 240° C. and 260° C. for a duration of between twenty and forty minutes.

4. A method in accordance with claim 3 in which the annealing of the resistivity-change material is carried out at a temperature ranging between 240° C. and 260° C. for a duration of between twenty-five and thirty-five minutes.

5. A method in accordance with claim 4 in which the annealing of the resistivity-change material is carried out at a temperature ranging between 240° C. and 260° C. for a duration of approximately thirty minutes.

6. A method in accordance with claim 1, in which the step of forming the layer of the resistivity-change material produces a nitrogen (N)-doped alloy of germanium (Ge) and tellurium (Te) in which the rate of nitrogen doping of the alloy is between 1.5% and 2.5%.

7. A method in accordance with claim 1, in which the step of forming the layer of the resistivity-change material produces a nitrogen (N)-doped alloy of germanium (Ge) and tellurium (Te), the germanium (Ge) and tellurium (Te) having a stoichiometric ratio close to one.

8. A method in accordance with claim 1, in which the step of formation of the layer of a resistivity-change material includes a deposition step where said layer is deposited by sputtering germanium and tellurium in a sealed chamber into which nitrogen has been introduced.

9. A non-volatile memory cell comprising a resistivity-change material configured to change state reversibly between at least two stable states presenting different electrical resistances, wherein the resistivity-change material is a nitrogen (N)-doped alloy of germanium (Ge) and of tellurium (Te), the nitrogen (N) doping being between 1.5% and 5%.

10. A memory cell in accordance with claim 9 in which the nitrogen (N) doping of the alloy is between 1.5% and 2.5%.

11. A memory cell in accordance with claim 10 in which the nitrogen (N) doping of the alloy is approximately 2%.

12. A memory cell in accordance with claim 9, in which the alloy of germanium (Ge) and tellurium (Te) has a stoichiometric ratio close to one.

13. A device comprising at least one memory cell in accordance with claim 9 and configured to be taken at least partially to a temperature equal to at least 100° C.

14. An automobile part comprising at least one memory cell in accordance with claim 9.

15. A method of changing a material state, comprising providing a memory cell in accordance with claim 9 and subjecting the memory cell to a temperature equal to at least 100° C.
